(19) United States
(12) Patent Application Publication
(10) Pub. No.: US 2023/0337444 A1
(43) Pub. Date: Oct. 19, 2023

(54) SOLAR CELL, PREPARATION METHOD FOR SOLAR CELL, AND PHOTOVOLTAIC MODULE

(71) Applicant: LONGI GREEN ENERGY TECHNOLOGY CO., LTD., Xi'an, Shaanxi (CN)

(72) Inventors: Junjie XIE, Xi'an, Shaanxi (CN); Chen XU, Xi'an, Shaanxi (CN); Zifeng LI, Xi'an, Shaanxi (CN); Zhao WU, Xi'an, Shaanxi (CN)

(21) Appl. No.: 18/028,491

(22) PCT Filed: Dec. 7, 2021
(86) PCT No.: PCT/CN2021/136125

§ 371 Date: Mar. 24, 2023

(30) Foreign Application Priority Data
Oct. 12, 2020 (CN) 202011086418.0

(51) Int. Cl. H10K 30/10; H10K 30/50; H10K 71/00

(52) U.S. Cl. CPC H10K 30/10; H10K 30/50; H10K 71/311; H10K 2101/70

(57) ABSTRACT

A solar cell, a preparation method for a solar cell, and a photovoltaic module, relating to the technical field of solar energy photovoltaics. The solar cell includes a crystalline silicon cell unit, and a down-conversion luminescence layer and a perovskite layer sequentially located on the light-facing surface of the crystalline silicon cell unit. The band gap of the perovskite layer becomes gradually smaller in the direction from the light-facing surface to the back surface. The band gap at the back surface of the perovskite layer is greater than or equal to the band gap of an absorption layer of the crystalline silicon cell unit. Because the band gap gradually decreases from large to small, the perovskite layer features a wide absorption spectrum, a long charge carrier free path, higher luminous efficiency, thus being able to broaden the spectral absorption range of the solar cell, and improve energy use and conversion efficiency. The complex processing of multi-layer battery superposition is avoided, the multiple film layer structure is simplified, losses in transmission of charge carriers between film layer interfaces and series structures are avoided, the conversion efficiency of the solar cell is further improved, and the processing difficulty is reduced, facilitating industrial production.

### CROSS REFERENCE TO RELEVANT APPLICATIONS

The present application claims the priority of the Chinese patent application filed on Oct. 12, 2020 before the Chinese Patent Office with the application number of 202011086418.0 and the title of “SOLAR CELL, PREPARATION METHOD FOR SOLAR CELL, AND PHOTOVOLTAIC MODULE”, which is incorporated herein in its entirety by reference.

### TECHNICAL FIELD

The present disclosure relates to the technical field of solar-energy photovoltaics, and particularly relates to a solar cell, a method for fabricating a solar cell and a photovoltaic module.

### BACKGROUND

In crystalline-silicon cells, silicon has a narrow band gap, and silicon is an indirect semiconductor. Therefore, after photons whose energy is highly higher than the band gap have been absorbed by the silicon, they cannot generate photon-generated carriers, and the energy of the photons is dissipated in the form of heat, whereby the energy of the visible spectrum cannot be sufficiently utilized.

Currently, what is frequently employed is to overlay wide-band-gap solar cells on crystalline-silicon cells, to fabricate tandem cells that can absorb and utilize photons in the visible spectrum that have higher energies at the same time. However, multiple film layers exist in the structure of the tandem cells, which results in a complicated fabricating process. Series-connecting components exist between the different cells, which further causes energy loss when the charge carriers are transferred between the different film layers and between the different cells, which restricts the energy conversion efficiency of the tandem cells.

### SUMMARY

The present disclosure provides a solar cell, a method for fabricating a solar cell and a photovoltaic module, which aims at reducing the energy loss in the transferring of the charge carriers, and increasing the conversion efficiency of the solar cell.

In the first aspect, an embodiment of the present disclosure provides a solar cell, wherein the solar cell includes a crystalline-silicon cell unit, and a down-conversion luminescent layer and a perovskite layer that are sequentially located on a light facing surface of the crystalline-silicon cell unit;
a band gap of the perovskite layer gradually decreases in a direction from a light facing surface to a shadow surface; and
a band gap at the shadow surface of the perovskite layer is greater than or equal to a band gap of an absorbing layer of the crystalline-silicon cell unit.

Optionally, the down-conversion luminescent layer includes a down-conversion luminescent material; and
the down-conversion luminescent material includes a perovskite material or a luminescent quantum dot.

Optionally, the perovskite layer is ABX₃;
A is selected from at least one of methylamine ion, formamidine ion, phenylethylamine ion, 1-menaphthylamine ion and caesium ion;
B is selected from at least one of lead ion and tin ion;
X is selected from at least one of bromine ion, iodide ion and chloride ion; and
by regulating an element distribution in the perovskite layer of the ABX₃ in a thickness direction, the band gap of the perovskite layer gradually decreases from the light facing surface to the shadow surface.

Optionally, the band gap of the perovskite layer at the light facing surface is 2 eV-3.06 eV;
the band gap of the perovskite layer at the shadow surface is 1.2 eV-1.5 eV; and
a band gap of the down-conversion luminescent material in the down-conversion luminescent layer is 1.2 eV-1.5 eV.

Optionally, a thickness of the perovskite layer is 10 nm-100 nm.

Optionally, the solar cell further includes an upper electrode, the upper electrode is formed at a hollowed-out position of the perovskite layer and the down-conversion luminescent layer, and the upper electrode does not directly contact the perovskite layer and the down-conversion luminescent layer.

In the second aspect, an embodiment of the present disclosure provides a method for fabricating a solar cell, wherein the solar cell is the solar cell according to the first aspect, and the method includes:
providing the crystalline-silicon cell unit;
forming sequentially the down-conversion luminescent layer and a narrow-band-gap perovskite layer on the light facing surface of the crystalline-silicon cell unit, wherein a band gap of the narrow-band-gap perovskite layer is greater than or equal to the band gap of the absorbing layer of the crystalline-silicon cell unit; and
contacting a wide-band-gap perovskite material with the narrow-band-gap perovskite layer to perform ion exchange, to form a perovskite layer whose energy bands are in a gradient distribution, wherein a phase state of the wide-band-gap perovskite material is any one of a solid phase, a gas phase and a liquid phase, and a band gap of the wide-band-gap perovskite material is greater than the band gap of the narrow-band-gap perovskite layer;
or
providing the crystalline-silicon cell unit;
forming the down-conversion luminescent layer on the light facing surface of the crystalline-silicon cell unit; and
coating a perovskite-precursor solution onto the down-conversion luminescent layer, whereby a perovskite precursor in the perovskite-precursor solution sequentially crystallizes to form the perovskite layer, wherein the perovskite precursor includes a two-dimensional perovskite precursor and a three-dimensional perovskite precursor.

Optionally, the phase state of the wide-band-gap perovskite material is a solid phase, and the step of contacting the wide-band-gap perovskite material with the narrow-band-gap perovskite layer to perform the ion exchange, to form the perovskite layer whose energy bands are in a gradient distribution includes:
adding a powder of the wide-band-gap perovskite material onto a surface of the narrow-band-gap perovskite layer, and heating to perform the ion exchange between the wide-band-gap perovskite material and the narrow-band-gap perovskite layer, to form the perovskite layer whose energy bands are in a gradient distribution.

Optionally, the phase state of the wide-band-gap perovskite material is a liquid phase, and the step of contacting the wide-band-gap perovskite material with the narrow-band-gap perovskite layer to perform the ion exchange, to form the perovskite layer whose energy bands are in a gradient distribution includes:
soaking the crystalline-silicon cell unit having the narrow-band-gap perovskite layer in the wide-band-gap perovskite material to perform the ion exchange, to form the perovskite layer whose energy bands are in a gradient distribution, wherein the wide-band-gap perovskite material includes any one of an ABX₃ perovskite solution, an AX precursor solution and a BX₂ precursor solution.

Optionally, the phase state of the wide-band-gap perovskite material is a gas phase, and the step of contacting the wide-band-gap perovskite material with the narrow-band-gap perovskite layer to perform the ion exchange, to form the perovskite layer whose energy bands are in a gradient distribution includes:
placing the crystalline-silicon cell unit having the narrow-band-gap perovskite layer in an atmosphere of the wide-band-gap perovskite material to perform the ion exchange, to form the perovskite layer whose energy bands are in a gradient distribution, wherein the wide-band-gap perovskite material includes any one of an ABX₃ perovskite vapour, an AX precursor vapour and a BX₂ precursor vapour.

In the third aspect, an embodiment of the present disclosure provides a photovoltaic module, wherein the photovoltaic module includes the solar cell according to the first aspect.

Optionally, the photovoltaic module includes the crystalline-silicon cell unit, a first encapsulation layer, the perovskite layer, the down-conversion luminescent layer and a cover-plate glass that are located on the light facing surface of the crystalline-silicon cell unit, and a second encapsulation layer and a back plate that are located on the shadow surface of the crystalline-silicon cell unit; and
the perovskite layer and the down-conversion luminescent layer are located between the light facing surface of the crystalline-silicon cell unit and the first encapsulation layer; or
the perovskite layer and the down-conversion luminescent layer are located between the first encapsulation layer and a shadow surface of the cover-plate glass.

### BRIEF DESCRIPTION OF THE DRAWINGS

In order to more clearly illustrate the technical solutions of the embodiments of the present disclosure, the figures that are required to describe the embodiments of the present disclosure will be briefly described below. Apparently, the figures that are described below are embodiments of the present disclosure, and a person skilled in the art can obtain other figures according to these figures without paying creative work.

FIG. 1 shows a schematic structural diagram of a solar cell according to an embodiment of the present disclosure;

FIG. 2 shows a schematic diagram of the energy bands of a perovskite layer according to an embodiment of the present disclosure;

FIG. 3 shows a schematic structural diagram of another solar cell according to an embodiment of the present disclosure;

FIG. 4 shows a schematic structural diagram of yet another solar cell according to an embodiment of the present disclosure;

FIG. 5 shows a flow chart of the steps of a method for fabricating a solar cell according to an embodiment of the present disclosure;

FIG. 6 shows a flow chart of the steps of another method for fabricating a solar cell according to an embodiment of the present disclosure;

FIG. 7 shows a schematic diagram of a perovskite structure according to an embodiment of the present disclosure;

FIG. 8 shows a schematic diagram of an ion-exchange process of a solid-phase wide-band-gap perovskite material according to an embodiment of the present disclosure;

FIG. 9 shows a schematic diagram of an ion-exchange process of a liquid-phase wide-band-gap perovskite material according to an embodiment of the present disclosure; and

FIG. 10 shows a schematic diagram of an ion-exchange process of a gas-phase wide-band-gap perovskite material according to an embodiment of the present disclosure.

### DETAILED DESCRIPTION

The technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

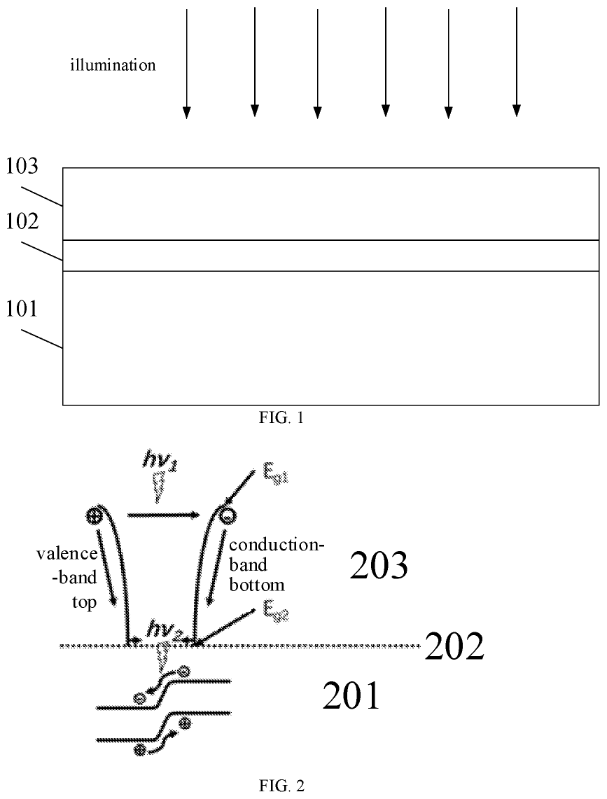

FIG. 1 shows a schematic structural diagram of a solar cell according to an embodiment of the present disclosure. Referring to FIG. 1, the solar cell 10 includes a crystalline-silicon cell unit 101, and a down-conversion luminescent layer 102 and a perovskite layer 103 that are sequentially located on the light facing surface of the crystalline-silicon cell unit 101;
the band gap of the perovskite layer 103 gradually decreases in the direction from the light facing surface to the shadow surface; and
the band gap at the shadow surface of the perovskite layer 103 is greater than or equal to the band gap of an absorbing layer of the crystalline-silicon cell unit 101.

In an embodiment of the present disclosure, the solar cell 10 includes a crystalline-silicon cell unit 101, a down-conversion luminescent layer 102 and a perovskite layer 103. The down-conversion luminescent layer 102 and the perovskite layer 103 are provided in the light facing direction of the crystalline-silicon cell unit 101. The perovskite layer 103 has a band gap that gradually decreases from the light facing surface to the shadow surface, and thus can absorb photons of different energies and having high energies to generate photon-generated carriers. The down-conversion luminescent layer 102 can perform radiative recombination to the photon-generated carriers to obtain photons of a lower energy, whereby the down-conversion luminescent layer 102 and the perovskite layer 103 can, before the sunlight enters the crystalline-silicon cell unit 101, convert the photons of a higher energy into the photons of a lower energy to which the crystalline-silicon cell unit 101 has a higher utilization ratio, to increase the conversion efficiency of the crystalline-silicon cell unit 101.

In an embodiment of the present disclosure, the band gap at the shadow surface of the perovskite layer 103 is greater than or equal to that of the crystalline-silicon cell unit 101, whereby the perovskite layer 103 can perform down-conversion to the photons that the absorbing layer of the crystalline-silicon cell unit 101 cannot effectively utilize. In addition, the band gap of the perovskite layer 103 gradually decreases in the direction from the light facing surface to the shadow surface; in other words, the band gap at the light facing surface is the highest, the band gap at the shadow surface is the lowest, and the band gap gradually decreases in the direction from the light facing surface to the shadow surface. Accordingly, the perovskite layer 103 can absorb the photons within a wide wavelength range from higher energies to lower energies, to perform down-conversion to photons of a wider range, thereby effectively increasing the conversion efficiency of the solar cell 10. Optionally, the gradual decreasing of the band gap according to the embodiments of the present disclosure may be decreasing of the band gap in a smooth trend from a higher band gap to a lower band gap, thereby eliminating the barrier potential, and increasing the efficiency of the migration of the charge carriers, and the band gap may also decrease in a multi-step gradient trend from a higher band gap to a lower band gap, which is not particularly limited in the embodiments of the present disclosure.

FIG. 2 shows a schematic diagram of the energy bands of a perovskite layer according to an embodiment of the present disclosure. As shown in FIG. 2, the figure shows the band gap of the crystalline-silicon cell unit 201 and the band gap of the perovskite layer 203. It can be seen that the band gap (E_{g1}) at the light facing surface of the perovskite layer 203 is the highest, the band gap (E_{g2}) at the shadow surface is the lowest, and the band gap gradually decreases from the light facing surface to the shadow surface. In this case, because the perovskite layer 203 has different band gaps at different depths, it can absorb photons of different energies at the different depths, whereby the perovskite layer 203 can absorb photons within the energy range between E_{g1} and E_{g2}, and generate charge carriers.

As shown in FIG. 2, the perovskite layer 203 absorbs photons of a higher energy (hv₁), and obtain photo-generated electrons and holes. The conduction-band bottom of the perovskite layer 203 gradually declines from the light facing surface to the shadow surface, and the electrons are transferred at the conduction-band bottom from a higher level to a lower level. The valence-band top gradually rises from the light facing surface to the shadow surface, and the holes are transferred at the valence-band top from a lower level to a higher level. Therefore, all of the photo-generated electrons and holes that are generated at the different depths of the perovskite layer 203 tend to be transferred to the shadow surface of the perovskite layer 203, and finally undergo radiative recombination at the down-conversion luminescent layer 202 to emit light. Because the perovskite layer 203 has a longer free path, by the driving of the gradually rising valence-band top and the gradually declining conduction-band bottom, the electrons and the holes have a higher transferring efficiency.

As shown in FIG. 2, at the down-conversion luminescent layer 202, the electrons and the holes can undergo radiative recombination, to obtain photons (hv₂) that have a lower energy than hv₁ and can be efficiently utilized by the crystalline-silicon cell unit 201. At the down-conversion luminescent layer 202, the conduction-band top and the valence-band bottom are closer, which facilitates the recombination between the electrons and the holes, to undergo radiative recombination to emit light.

As shown in FIG. 2, the down-conversion luminescent layer 202 undergoes radiative recombination to emit light, and the absorbing layer of the crystalline-silicon cell unit 201 can absorb the hv₂, and can efficiently utilize the hv₂.

Optionally, the material of the perovskite layer 203 is ABX₃.

In an embodiment of the present disclosure, the perovskite material may be organic-inorganic hybrid perovskite, may also be inorganic perovskite, may also be leadless-system perovskite, and so on. Optionally, ABX₃ may be used to represent the material of the perovskite layer, wherein A is a monovalent cation, B is a divalent metal cation, and X is a halide ion. A, B and X may individually be one ion, and may also individually be a mixture of two or more ions. By regulating the types of the ions, the mixing proportion of the ions and so on, the magnitude and the variation trend of the band gap of the perovskite layer 203 can be regulated, whereby the band gap of the perovskite layer 203 gradually decreases from the light facing surface to the shadow surface.

In an embodiment of the present disclosure, a wide-band-gap material and a narrow-band-gap material may be contacted, to enable the ions to migrate along the ion-concentration gradient, so that the ions of the wide-band-gap material migrate to the narrow-band-gap material, and the ions of the narrow-band-gap material migrate to the wide-band-gap material. Because the magnitude of the band gap is related to the types and the concentrations of the ions, the perovskite layer whose band gap gradually changes can be formed by regulating the types and the concentrations of the ions. When A, B and X are individually a mixture of two or more ions, A and A′ may be used to represent different A ions, B and B′ represent different B ions, and C and C′ represent different C ions. The B and B′ ions construct the main frame of the crystal structure of the perovskite material, and their migration requires a very high energy (>2 eV), and might result in the collapse of the crystal structure of the material. Therefore, the B and B′ ions usually do not migrate. Optionally, in an embodiment of the present disclosure, the band gap of ABX₃ may be greater than that of A′B′X′₃ by selecting different A and A′ ions, or selecting different X and X′ ions, or selecting different A and A′ ions and different X and X′ ions at the same time. After the contacting, because the concentrations of the ions in the two materials are different, the ions migrate along the ion-concentration gradient, to obtain the perovskite layer whose band gap gradually changes. The types of the ions are not particularly limited in the embodiments of the present disclosure.

Optionally, A is selected from at least one of methylamine ion, formamidine ion, phenylethylamine ion, 1-menaphthylamine ion and caesium ion.

In an embodiment of the present disclosure, A is selected from monovalent cations such as methylamine ion, formamidine ion, phenylethylamine ion, 1-menaphthylamine ion and caesium ion, wherein A may be one type of monovalent cation, and may also be different types of monovalent cations, represented by A and A′, and in this case the band gap of ABX₃ should be different from that of A′BX₃. Generally, when the other ions are the same, the relation of the band gaps of the above-described monovalent cations is 1-menaphthylamine ion (NMA)>phenylethylamine ion (PEA)>caesium ion (Cs)>methylamine ion (MA)>formamidine ion (FA).

In this case, when A is NMA, A′ may be at least one of PEA, Cs, MA and FA, and when A is PEA, A′ may be at least one of Cs, MA and FA, whereby the band gap of ABX₃ is greater than that of A′BX₃. The rest may be done in the same manner.

B is selected from at least one of lead ion and tin ion.

In an embodiment of the present disclosure, B is selected from divalent metal cations such as lead ion and tin ion, wherein B may be one type of divalent metal cation, and may also be two types of divalent metal cations, represented by B and B′, whereby the band gap of ABX₃ is different from that of AB′X3. Generally, when the other ions are the same, the relation of the band gaps of the above-described divalent metal cations is lead ion (Pb)>tin ion (Sn). In this case, when B is Pb, B′ may be Sn, and the rest can be done in the same manner, whereby the band gap of ABX₃ is greater than that of AB′X3. However, in practical applications, because B and B′ do not participate in the ion migration, at least one of A, A′, X and X′ is different so that the band gaps of the materials are different. In this case, even if B is Sn and B′ is Pb, the band gap of ABX₃ in the formed material system might be greater than that of A′B′X′₃. In an embodiment of the present disclosure, the band gap may be based on the actually measured band gap of the perovskite material, and the selection of the different ions is not particularly limited.

X is selected from at least one of bromine ion, iodide ion and chloride ion.

In an embodiment of the present disclosure, X may be selected from halide ions such as bromine ion, iodide ion and chloride ion, wherein X may be one type of halide ion, and may also be different types of halide ions, represented by X and X′, whereby the band gap of ABX₃ is different from that of ABX′₃. Generally, when the other ions are the same, the relation of the band gaps of the above-described halide ions is chloride ion (Cl)>bromine ion (Br)>iodide ion (I). In this case, when X is Cl, X′ may be at least one of Br and I, and the rest can be done in the same manner, whereby the band gap of ABX₃ is greater than that of ABX′₃.

In an embodiment of the present disclosure, because the halogen has a higher influence on the changing of the band gap in the material system, when X is a wide-band-gap halide ion, X′ is a narrow-band-gap halide ion and the other ions are of different types, the relations of the band gaps corresponding to the other ions may also be opposite. In this case, the band gap of ABX₃ in the material system is greater than that of A′B′X′₃, which is not particularly limited in the embodiments of the present disclosure.

By regulating the element distribution in the perovskite layer of the ABX₃ in the thickness direction, the band gap of the perovskite layer gradually decreases from the light facing surface to the shadow surface.

In an embodiment of the present disclosure, the thickness direction may be the direction of the light incidence of the perovskite layer. The regulation on the element distribution of ABX₃ in the perovskite layer may be the regulation on the types, the proportions, the concentrations and so on of the above-described ions in the perovskite layer. For example, in the perovskite layer, the ions of higher band gaps are caused to be more distributed at the light facing surface of the perovskite layer, and the ions of lower band gaps are more distributed at the shadow surface of the perovskite layer, whereby the band gap of the perovskite layer gradually decreases from the light facing surface to the shadow surface.

Optionally, the band gap of the perovskite layer at the light facing surface is 2 eV-3.06 eV; the band gap of the perovskite layer at the shadow surface is 1.2 eV-1.5 eV; and a band gap of the down-conversion luminescent material in the down-conversion luminescent layer is 1.2 eV-1.5 eV.

In an embodiment of the present disclosure, the photon energy with which the perovskite layer 203 firstly performs conversion is required to be greater than or equal to the upper limit that the crystalline-silicon cell unit 201 can absorb, to prevent participation in the down-conversion of the photons in the sunlight that the crystalline-silicon cell unit 201 can absorb, which results in resource waste. According to the range of the band gap of the perovskite material used in the perovskite layer 203, the band gap of the crystalline-silicon cell unit 201 and the maximum limit of the absorbed visible light, a person skilled in the art may select the ranges of the different band gaps at the light facing surface and the shadow surface of the perovskite layer 203. For example, when the band gap of the crystalline-silicon cell unit 201 is 1.12 eV, the band gap of the perovskite layer 203 at the light facing surface is 2 eV-3.06 eV, and the band gap at the shadow surface is 1.2 eV-1.5 eV, which is not particularly limited in the embodiments of the present disclosure.

In an embodiment of the present disclosure, the down-conversion luminescent layer 202 is located between the shadow surface of the perovskite layer 203 and the light facing surface of the crystalline-silicon cell unit 201. The down-conversion luminescent material in the down-conversion luminescent layer 202 can collect the photo-generated electrons and holes of the perovskite layer 203, and undergo radiative recombination to emit light to the crystalline-silicon cell unit 201. In this case, in order to ensure the efficiency of the radiative recombination, the band gap of the down-conversion luminescent material may, by referring to the band gap at the shadow surface of the perovskite layer 203, be 1.2 eV-1.5 eV. A person skilled in the art may also add other materials into the down-conversion luminescent layer according to practical demands, which is not particularly limited in the embodiments of the present disclosure.

Optionally, the thickness of the perovskite layer 203 is 10 nm-100 nm.

In an embodiment of the present disclosure, because the perovskite material has a high absorption coefficient, in order to prevent an excessively high thickness of the perovskite layer 203, which causes self-absorption, heat generation and so on, whereby the low-energy photons emitted by the down-conversion luminescent layer 202 are not easily absorbed by the crystalline-silicon cell unit 201, the thickness of the perovskite layer 203 may be any numerical value within the range of 10 nm-100 nm, for example, 10 nm, 15 nm, 30 nm, 60 nm, 80 nm and 100 nm, which is not particularly limited in the embodiments of the present disclosure.

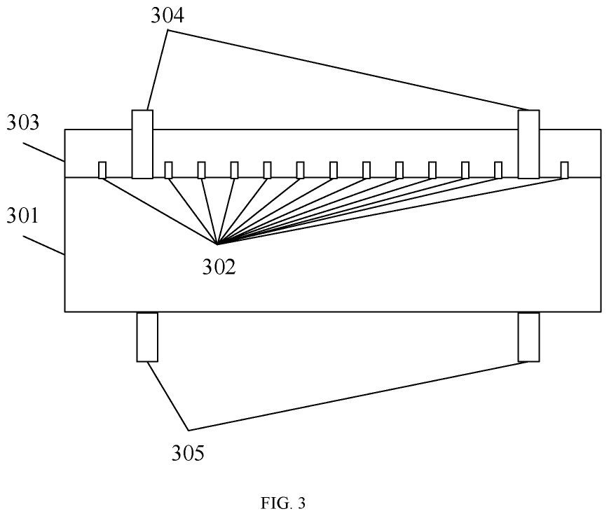

FIG. 3 shows a schematic structural diagram of another solar cell according to an embodiment of the present disclosure. Referring to FIG. 3, the solar cell 30 includes a crystalline-silicon cell unit 301, and a down-conversion luminescent layer 302 and a perovskite layer 303 that are sequentially located on the light facing surface of the crystalline-silicon cell unit 301;
the band gap of the perovskite layer 303 gradually decreases in the direction from the light facing surface to the shadow surface; and
the band gap at the shadow surface of the perovskite layer 303 is greater than or equal to the band gap of an absorbing layer of the crystalline-silicon cell unit 301.

In an embodiment of the present disclosure, the crystalline-silicon cell unit 301 and the perovskite layer 303 may correspondingly be with reference to the above relevant description on FIG. 1 and FIG. 2, and, in order to avoid replication, are not discussed herein further.

Optionally, the down-conversion luminescent layer 302 includes a down-conversion luminescent material.

Optionally, the down-conversion luminescent material includes a perovskite material or a luminescent quantum dot.

In an embodiment of the present disclosure, the down-conversion luminescent layer 302 may include a down-conversion luminescent material. The down-conversion luminescent material may be the perovskite material or the luminescent quantum dot. The band gap of the perovskite material may be uniformly distributed, and the perovskite material is prepared by using different perovskite materials with the same band gaps or the same perovskite material. The luminescent quantum dot refers to a semiconductor nano-sized structure that can bind charge carriers. Optionally, the down-conversion luminescent material may be luminescent quantum dots that are embedded into the shadow surface of the perovskite layer 303, and after the electrons and the holes have been converged to the shadow surface, they may be injected into the luminescent quantum dots, and undergo radiative recombination in the luminescent quantum dots, to release photons of a lower energy. Based on the quantum confinement effect of the luminescent quantum dots, in the luminescent quantum dots, the electrons and the holes have a higher luminous efficiency.

In an embodiment of the present disclosure, when the band gap of the perovskite layer 303 is 1.2 eV-1.5 eV, the band gap of the luminescent quantum dots may be, within the range of 1.2 eV-1.5 eV, equal to the band gap at the shadow surface of the perovskite layer 303, and may also be unequal to the band gap at the shadow surface of the perovskite layer 303. Optionally, when the band gap of the luminescent quantum dots and the band gap at the shadow surface of the perovskite layer 303 are unequal, the luminescent quantum dots can form quantum wells on the energy-band structure of the solar cell 30, thereby increasing the probability of the radiative recombination of the luminescent quantum dots, to increase the luminous efficiency of the solar cell 30.

In an embodiment of the present disclosure, when the band gap of the luminescent quantum dots and the band gap at the shadow surface of the perovskite layer 303 are unequal, the band gap of the luminescent quantum dots may be greater than the band gap at the shadow surface of the perovskite layer 303, and may also be less than the band gap at the shadow surface of the perovskite layer 303. When the band gap of the luminescent quantum dots is less than the band gap at the shadow surface of the perovskite layer 303, the luminescent quantum dots can more fully absorb the charge carriers generated by the perovskite layer 303. Optionally, the band gap of the luminescent quantum dots may also be equal to the band gap of the perovskite layer 303, so that the electrons and the holes more easily enter the luminescent quantum dots, to increase the conversion efficiency.

Optionally, the solar cell 30 further includes an upper electrode 304, the upper electrode 304 is formed at a hollowed-out position of the perovskite layer 303 and the down-conversion luminescent layer 302, and the upper electrode 304 does not directly contact the perovskite layer 303 and the down-conversion luminescent layer 302.

In an embodiment of the present disclosure, the upper electrode 304 refers to an electrode of the solar cell 30 that is located on the light facing surface of the crystalline-silicon cell unit 301. As shown in FIG. 3, the upper electrode 304 is connected to the light facing surface of the crystalline-silicon cell unit 301, passes through the hollowed-out position of the down-conversion luminescent layer 302 and the perovskite layer 303, and protrudes. In order to prevent conduction between the upper electrode 304 and the perovskite layer 303 or the down-conversion luminescent layer 302, it may be configured that the upper electrode 304 and the perovskite layer 303 and the down-conversion luminescent layer 302 do not directly contact. For example, the upper electrode 304 does not contact either the perovskite layer 303 or the down-conversion luminescent layer 302, or the upper electrode 304 is provided with insulating layers with both of the down-conversion luminescent layer 302 and the perovskite layer 303, which is not particularly limited in the embodiments of the present disclosure. In addition, a lower electrode 305 may be provided on the shadow surface of the crystalline-silicon cell unit 301.

In an embodiment of the present disclosure, the solar cell 30, besides the above-described functional layers, may further include other functional layers, for example, a passivation layer, which is not particularly limited in the embodiments of the present disclosure.

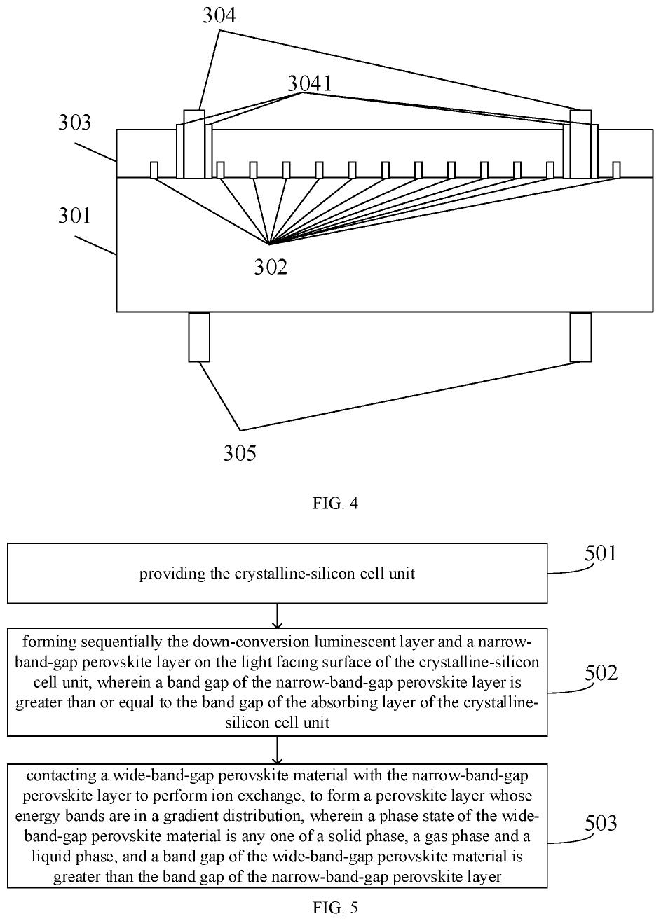

FIG. 4 shows a schematic structural diagram of yet another solar cell according to an embodiment of the present disclosure. As shown in FIG. 4, on the basis of FIG. 3, an insulating layer 3041 is provided between the upper electrode 304 and the perovskite layer 303, and the insulating layer 3041 wraps the upper electrode 304, to prevent conduction between the upper electrode 304 and the down-conversion luminescent layer 302 or the perovskite layer 303. A person skilled in the art may select the material of the insulating layer 3041 according to practical demands and process conditions, which is not particularly limited in the embodiments of the present disclosure.

The solar cell according to the embodiments of the present disclosure includes the crystalline-silicon cell unit, the perovskite layer and the down-conversion luminescent layer, and the down-conversion luminescent layer and the perovskite layer are sequentially located on the light facing surface of the crystalline-silicon cell unit; and the band gap of the perovskite layer gradually decreases in the direction from the light facing surface to the shadow surface, and the band gap of the shadow surface is greater than or equal to the band gap of the absorbing layer of the crystalline-silicon cell unit. Therefore, the perovskite layer can absorb the photons of different energies that the crystalline-silicon cell unit cannot effectively utilize, and generate electrons and holes, and the electrons and the holes, when driven by the band-gap-energy-band structure, are transferred to the shadow surface of the perovskite layer, and undergo radiative recombination in the down-conversion luminescent layer, to release photons within the wavelength range that the crystalline-silicon cell unit can efficiently utilize. The perovskite layer and the down-conversion luminescent layer according to the embodiments of the present disclosure can cooperate to perform down-conversion to photons of different high energies and a wide wavelength range. Because the perovskite layer has a wide absorption spectrum, a long charge-carrier free path and a high luminous efficiency, it can effectively widen the range of the spectral absorption of the solar cell, and increase the efficiency of its energy utilization and conversion. Furthermore, the perovskite layer and the down-conversion luminescent layer are added merely on the crystalline-silicon cell unit, which avoids the complicated process of multilayer cell overlaying, simplifies the multi-film-layer structure, prevents the loss caused when the charge carriers are transferred at the film-layer interface and between the series-connecting components, further increases the conversion efficiency of the solar cell, and reduces the process difficulty and the fabricating cost, to facilitate the industrial production.

FIG. 5 shows a flow chart of the steps of a method for fabricating a solar cell according to an embodiment of the present disclosure. As shown in FIG. 5, the method may include:

Step 501: providing the crystalline-silicon cell unit.

In an embodiment of the present disclosure, the crystalline-silicon cell unit may be a monocrystalline-silicon cell, a polycrystalline-silicon cell and so on, and may also be a microcrystalline-silicon cell, a nanocrystalline-silicon cell and so on. The particular structure of the crystalline-silicon cell unit is not limited in the embodiments of the present disclosure.

Step 502: forming sequentially the down-conversion luminescent layer and a narrow-band-gap perovskite layer on the light facing surface of the crystalline-silicon cell unit, wherein a band gap of the narrow-band-gap perovskite layer is greater than or equal to the band gap of the absorbing layer of the crystalline-silicon cell unit.

In an embodiment of the present disclosure, ion exchange may happen between the perovskite materials. In the perovskite materials the ion migration energy is low, and the ions easily migrate along the concentration gradient. In this case, the narrow-band-gap perovskite material and the wide-band-gap perovskite material may be caused to contact. Because the band gaps of the perovskite materials are unequal, and the types and the proportions of the ions are different, by the driving by the concentration gradient, the changing of the band gaps of the perovskite materials is regulated by the ion migration. Optionally, because the band gap of the prepared perovskite layer should gradually decrease from the light facing surface to the shadow surface, firstly, the down-conversion luminescent layer and the narrow-band-gap perovskite layer may be sequentially formed on the light facing surface of the crystalline-silicon cell unit, wherein the band gap of the narrow-band-gap perovskite layer is greater than or equal to the band gap of the absorbing layer of the crystalline-silicon cell unit. The band gap of the down-conversion luminescent layer may be with reference to the band gap of the narrow-band-gap perovskite layer.

Step 503: contacting a wide-band-gap perovskite material with the narrow-band-gap perovskite layer to perform ion exchange, to form a perovskite layer whose energy bands are in a gradient distribution, wherein a phase state of the wide-band-gap perovskite material is any one of a solid phase, a gas phase and a liquid phase, and a band gap of the wide-band-gap perovskite material is greater than the band gap of the narrow-band-gap perovskite layer.

In an embodiment of the present disclosure, the wide-band-gap perovskite material may be contacted with the narrow-band-gap perovskite layer on the light facing surface of the crystalline-silicon cell unit, wherein the band gap of the wide-band-gap perovskite material should be greater than the band gap of the narrow-band-gap perovskite layer. The ions in the wide-band-gap perovskite material migrate into the narrow-band-gap perovskite layer, and replace the ions in the narrow-band-gap perovskite layer, to form the perovskite layer, thereby obtaining the solar cell including the crystalline-silicon cell unit, the down-conversion luminescent layer and the perovskite layer. By the driving by the concentration gradient, the ions of the wide-band-gap perovskite material present, in the narrow-band-gap perovskite layer, a distribution trend of gradually decreasing in the direction from the light facing surface to the shadow surface, whereby the band gap of the perovskite layer gradually decreases in the direction from the light facing surface to the shadow surface, and the energy bands are in a gradient distribution. Optionally, the phase state of the wide-band-gap perovskite material may be a solid phase, a gas phase, a liquid phase and so on. The wide-band-gap perovskite materials of a solid phase or a liquid phase have higher ion-migration speeds, and usually they can reach an ion-migration depth of hundreds of nanometers within a couple of seconds to tens of seconds. A person skilled in the art may select the temperature and the duration of the contacting between the wide-band-gap perovskite material and the narrow-band-gap perovskite layer on the light facing surface of the crystalline-silicon cell unit according to practical application demands, preparation process conditions and so on, which is not particularly limited in the embodiments of the present disclosure.

Optionally, the phase state of the wide-band-gap perovskite material is the solid phase, and the step 502 includes:

Step S11: adding a powder of the wide-band-gap perovskite material onto a surface of the narrow-band-gap perovskite layer, and heating to perform the ion exchange between the wide-band-gap perovskite material and the narrow-band-gap perovskite layer, to form the perovskite layer whose energy bands are in a gradient distribution.

In an embodiment of the present disclosure, when the wide-band-gap material is of the solid phase, this step may include covering the powder of the wide-band-gap material onto the narrow-band-gap perovskite layer, and subsequently increasing the temperature, whereby by the driving by the concentration difference and the temperature the wide-band-gap material and the narrow-band-gap perovskite layer undergo ion exchange therebetween, whereby the band gap of the perovskite layer gradually decreases from the exterior to the interior. Both of the wide-band-gap perovskite material and the narrow-band-gap perovskite layer are formed by a perovskite material. In order to obtain the different band gaps, at least one of the migratable A ions and X ions of the wide-band-gap perovskite material and the narrow-band-gap perovskite layer is different, and the band gap of the wide-band-gap material is caused to be greater than that of the narrow-band-gap perovskite layer. Optionally, the difference may be the difference in the ion types, the difference in the ion concentrations, and so on.

Optionally, the phase state of the wide-band-gap perovskite material is a liquid phase, and the step 502 includes:

Step S21: soaking the crystalline-silicon cell unit having the narrow-band-gap perovskite layer in the wide-band-gap perovskite material to perform the ion exchange, to form the perovskite layer whose energy bands are in a gradient distribution, wherein the wide-band-gap perovskite material includes any one of an ABX₃ perovskite solution, an AX precursor solution and a BX₂ precursor solution.

In an embodiment of the present disclosure, when the wide-band-gap perovskite material is of the liquid phase, the narrow-band-gap perovskite layer may be soaked in it, so that the wide-band-gap perovskite material and the narrow-band-gap perovskite layer contact. Optionally, the depth by which the crystalline-silicon cell unit having the narrow-band-gap perovskite layer is soaked in the wide-band-gap material in the direction from the light facing surface to the shadow surface may be controlled. For example, the crystalline-silicon cell unit and the narrow-band-gap perovskite layer on the light facing surface of the crystalline-silicon cell unit may be soaked together in the solution of the wide-band-gap perovskite material, and the soaking depth may also be controlled to soak the narrow-band-gap perovskite layer in the wide-band-gap perovskite material, and not soak the crystalline-silicon cell unit in the wide-band-gap perovskite material, which is not particularly limited in the embodiments of the present disclosure. In addition, the wide-band-gap perovskite material may be a supersaturated solution, thereby preventing solution loss of the narrow-band-gap perovskite layer.

In an embodiment of the present disclosure, the wide-band-gap perovskite material may be an ABX₃ perovskite solution. Both of the wide-band-gap perovskite material and the narrow-band-gap perovskite layer are formed by a perovskite material. In order to obtain the different band gaps, at least one of the migratable A ions and X ions of the wide-band-gap perovskite material and the narrow-band-gap perovskite layer is different, and the band gap of the wide-band-gap material is caused to be greater than that of the narrow-band-gap perovskite layer. Optionally, the difference may be the difference in the ion types, the difference in the ion concentrations, and so on. Optionally, according to the types of the migrating ions, the wide-band-gap perovskite material may also be any one of an AX precursor solution and a BX₂ precursor solution. When the migrating ion is an A ion, an X ion or an AX ion, the AX precursor solution may be selected, in which case the narrow-band-gap perovskite material is at least one of A′BX₃, ABX′₃ and A′BX′₃. When the migrating ion is an X ion, the BX₂ precursor solution may be selected, and the X′ ion of the narrow-band-gap perovskite layer is different from the X ion. A person skilled in the art may select different precursor solutions as the wide-band-gap perovskite material according to demands, which is not particularly limited in the embodiments of the present disclosure.

In an embodiment of the present disclosure, after the ion migration has ended, the residual wide-band-gap perovskite material may be washed by using a solvent indissolvable to the perovskite material, so as to prevent the residual wide-band-gap perovskite material from forming another wide-band-gap perovskite layer on the light facing surface of the formed perovskite layer, which affects the fabricating process.

Optionally, the phase state of the wide-band-gap perovskite material is a gas phase, and the step 503 includes:

Step S31: placing the crystalline-silicon cell unit having the narrow-band-gap perovskite layer in an atmosphere of the wide-band-gap perovskite material to perform the ion exchange, to form the perovskite layer whose energy bands are in a gradient distribution, wherein the wide-band-gap perovskite material includes any one of an ABX₃ perovskite vapour, an AX precursor vapour and a BX₂ precursor vapour.

In an embodiment of the present disclosure, when the wide-band-gap perovskite material is of the gas phase, the narrow-band-gap perovskite layer may be placed into the atmosphere of the wide-band-gap perovskite material. Optionally, the depth by which the crystalline-silicon cell unit having the narrow-band-gap perovskite layer is placed into the atmosphere of the wide-band-gap perovskite material from the light facing surface to the shadow surface may be controlled, which may particularly correspondingly be with reference to the above relevant description on the step S21, and, in order to avoid replication, is not discussed herein further.

In an embodiment of the present disclosure, the wide-band-gap perovskite material may be an ABX₃ perovskite vapour. Both of the wide-band-gap perovskite material and the narrow-band-gap perovskite layer are formed by a perovskite material. In order to obtain the different band gaps, at least one of the migratable A ions and X ions of the wide-band-gap perovskite material and the narrow-band-gap perovskite layer is different, and the band gap of the wide-band-gap material is caused to be greater than that of the narrow-band-gap perovskite layer. Optionally, the difference may be the difference in the ion types, the difference in the ion concentrations, and so on. Optionally, according to the types of the migrating ions, the wide-band-gap perovskite material may also be any one of an AX precursor vapour and a BX₂ precursor vapour. When the migrating ion is an A ion, an X ion or an AX ion, the AX precursor vapour may be selected, in which case the narrow-band-gap perovskite material is at least one of A′BX₃, ABX′₃ and A′BX′₃. When the migrating ion is an X ion, the BX₂ precursor vapour may be selected, and the X′ ion of the narrow-band-gap perovskite layer is different from the X ion. A person skilled in the art may select different precursor vapours as the wide-band-gap perovskite material according to demands, which is not particularly limited in the embodiments of the present disclosure.

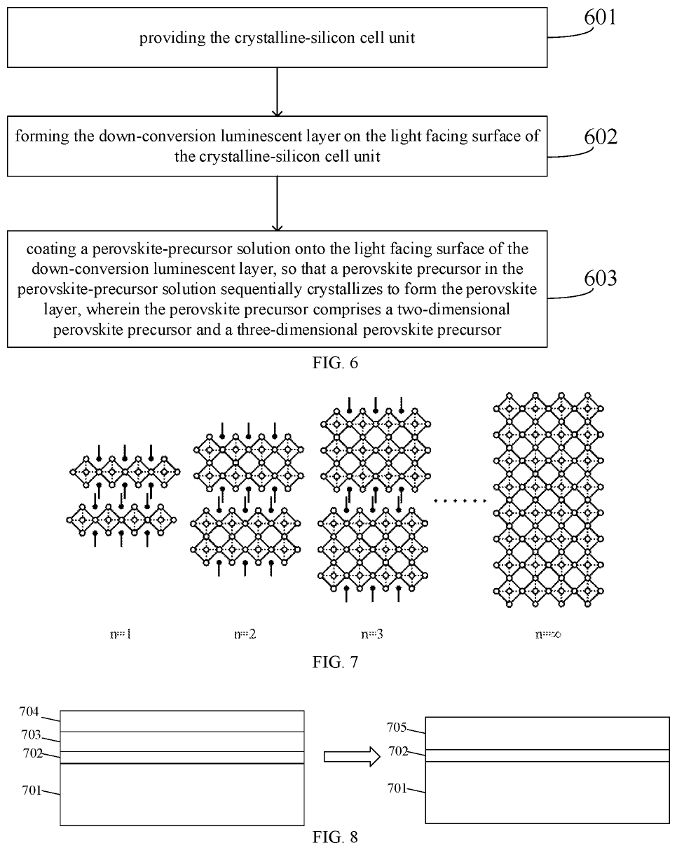

FIG. 6 shows a flow chart of the steps of another method for fabricating a solar cell according to an embodiment of the present disclosure. As shown in FIG. 6, the method may include:

Step 601: providing the crystalline-silicon cell unit.

In an embodiment of the present disclosure, the step 601 may correspondingly be with reference to the above relevant description on the step 501, and, in order to avoid replication, is not discussed herein further.

Step 602: forming the down-conversion luminescent layer on the light facing surface of the crystalline-silicon cell unit.

Step 603: spread-coating a perovskite-precursor solution onto the light facing surface of the down-conversion luminescent layer, whereby a perovskite precursor in the perovskite-precursor solution sequentially crystallizes to form the perovskite layer, wherein the perovskite precursor includes a two-dimensional perovskite precursor and a three-dimensional perovskite precursor.

In an embodiment of the present disclosure, the perovskite layer whose energy bands are in a gradient distribution may be formed by means of sequential crystallization of three-dimensional-quasi-two-dimensional-two-dimensional perovskite. A perovskite-precursor solution that contains both of a two-dimensional perovskite precursor and a three-dimensional perovskite precursor may be spread-coated onto the light facing surface of the down-conversion luminescent layer, and at this point the perovskite precursors undergo sequential crystallization, to sequentially form, in the direction from the shadow surface to the light facing surface, a perovskite layer of a three-dimensional-qua si-two-dimensional-two-dimensional perovskite structure.

FIG. 7 shows a schematic diagram of a perovskite structure according to an embodiment of the present disclosure. As shown in FIG. 7, when three-dimensional perovskite is formed on the light facing surface of the down-conversion luminescent layer, its structure corresponds to the case in which n=∞. During the sequential crystallization, the n value gradually decreases, whereby a quasi-two-dimensional perovskite layer is gradually formed. When n=1, a two-dimensional perovskite layer is formed. Because if the n value is lower, the band gap of the perovskite material is higher, the band gap of the sequentially crystallized perovskite layer gradually decreases in the direction from the light facing surface to the shadow surface. Optionally, in the embodiments of the present disclosure, the band gaps at the light facing surface and the shadow surface of the perovskite layer may be regulated by regulating the proportion of the two-dimensional perovskite precursor and the three-dimensional perovskite precursor and the ion types.

In an embodiment of the present disclosure, the two-dimensional perovskite precursor may correspondingly be with reference to the above relevant description on the wide-band-gap perovskite material, and the three-dimensional perovskite precursor may correspondingly be with reference to the above relevant description on the narrow-band-gap perovskite material, which, in order to avoid replication, is not discussed herein further. Optionally, the two-dimensional perovskite precursor may be an A ion of a higher ionic radius, for example, NMA (1-naphthylmethylamine) and PEA (phenylethylamine).

Example 1 Ion exchange of the solid-phase wide-band-gap perovskite material
providing the crystalline-silicon cell unit;
forming sequentially the down-conversion luminescent layer and a FAPbI₃ narrow-band-gap perovskite layer on the light facing surface of the crystalline-silicon cell unit; and
spreading a FAPbBr₃ perovskite powder onto the light facing surface of the FAPbI₃ narrow-band-gap perovskite layer, and heating to cause the FAPbI₃ narrow-band-gap perovskite layer and the FAPbBr₃ perovskite powder to undergo ion exchange, to form the perovskite layer.

FIG. 8 shows a schematic diagram of an ion-exchange process of a solid-phase wide-band-gap perovskite material according to an embodiment of the present disclosure. As shown in FIG. 8, a layer of the FAPbBr₃ perovskite powder 704 is spread onto the light facing surface of the FAPbI₃ narrow-band-gap perovskite layer 703 on the down-conversion luminescent layer 702. At this point, the I ions and the Br ions migrate by the driving by the concentration difference and the temperature, the FAPbI₃ narrow-band-gap perovskite layer 703 (of a band gap of 1.47 eV) and the FAPbBr₃ perovskite powder 704 (of a band gap of 2.2 eV) undergo ion exchange therebetween, and the I ions in the FAPbI₃ narrow-band-gap perovskite layer 703 are substituted by the Br ions. If the I ions are closer to the light facing surface, they are substituted more, the concentration of the Br ions is higher, and the band gap is higher. Finally, a FAPb(I₁₋ₓBrₓ)₃ perovskite layer 705 whose Br-ion concentration gradually decreases in the direction from the light facing surface to the shadow surface is formed. The band gap of the perovskite layer 705 gradually decreases in the direction from the light facing surface to the shadow surface, to form a perovskite layer of a gradually changing band gap. The perovskite layer prepared in Example 1 can absorb photons of the energy between 2.2 eV-1.47 eV, and emit photons of the wavelength of 845 nm, to realize the function of down-conversion.

Example 2 Ion exchange of the liquid-phase wide-band-gap perovskite material providing the crystalline-silicon cell unit;
forming sequentially the down-conversion luminescent layer and a FAPbI₃ narrow-band-gap perovskite layer on the light facing surface of the crystalline-silicon cell unit; and
soaking the crystalline-silicon cell unit having the FAPbI₃ narrow-band-gap perovskite layer in a MAPbBr₃ solution, whereby the FAPbI₃ narrow-band-gap perovskite layer and the MAPbBr₃ solution undergo ion exchange, to form the perovskite layer.

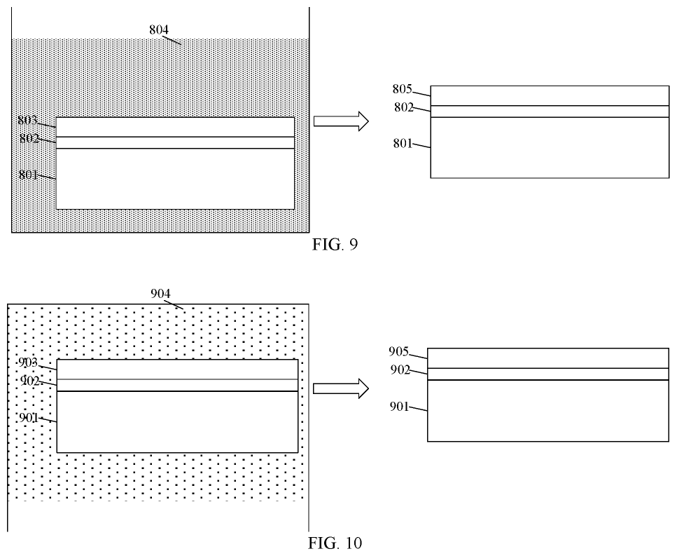

FIG. 9 shows a schematic diagram of an ion-exchange process of a liquid-phase wide-band-gap perovskite material according to an embodiment of the present disclosure. As shown in FIG. 9, a crystalline-silicon cell unit 801 having a FAPbI₃ narrow-band-gap perovskite layer 803 is soaked in a MAPbBr₃ solution 804. The I ions, the Br ions, the FA ions and the MA ions migrate by the driving by the concentration difference, and the FAPbI₃ narrow-band-gap perovskite layer 803 (of a band gap of 1.47 eV) and the MAPbBr₃ solution 804 (of a band gap of 2.3 eV) undergo ion exchange therebetween, to form a FA_{1-y}MA_{y}Pb(I₁₋ₓBrₓ)₃ perovskite layer 805 whose band gap gradually decreases from the light facing surface to the shadow surface. The prepared perovskite layer 805 can absorb photons within the energy range of 2.3-1.47 eV, and emit photons of the wavelength of 845 nm, to realize the function of down-conversion.

Example 3 Ion exchange of the gas-phase wide-band-gap perovskite material
providing the crystalline-silicon cell unit;
forming sequentially the down-conversion luminescent layer and a FAPbI₃ narrow-band-gap perovskite layer on the light facing surface of the crystalline-silicon cell unit; and
placing the crystalline-silicon cell unit having the FAPbI₃ narrow-band-gap perovskite layer in the atmosphere of a CsPbBr₃ vapour, whereby the FAPbI₃ narrow-band-gap perovskite layer and the CsPbBr₃ vapour undergo ion exchange, to form the perovskite layer.

FIG. 10 shows a schematic diagram of an ion-exchange process of a gas-phase wide-band-gap perovskite material according to an embodiment of the present disclosure. As shown in FIG. 9, a crystalline-silicon cell unit 901 having a FAPbI₃ narrow-band-gap perovskite layer 903 is placed in the atmosphere of a CsPbBr₃ vapour 904. The FA ions and the Cs ions migrate by the driving by the concentration difference, the FAPbI₃ narrow-band-gap perovskite layer 903 and the CsPbBr₃ vapour 904 (of a band gap of 2.3 eV) undergo ion exchange, to form a Cs_{y}FA_{1-y}Pb(BrₓI₁₋ₓ)₃ perovskite layer 905 whose band gap gradually decreases from the light facing surface to the shadow surface. The prepared perovskite layer 905 can absorb photons within the energy range of 2.3-1.47 eV, and emit photons of the wavelength of 845 nm, to realize the function of down-conversion.

Example 4 Sequential crystallization of three-dimensional-quasi-two-dimensional-two-dimensional perovskite
providing the crystalline-silicon cell unit;
forming the down-conversion luminescent layer on the light facing surface of the crystalline-silicon cell unit; and
spread-coating a perovskite-precursor solution onto the down-conversion luminescent layer, and heating to cause the solvent to volatilize to cause the perovskite precursor in the perovskite-precursor solution to undergo sequential crystallization to form the perovskite layer, wherein the perovskite precursor contains an (NMA)₂PbI₄ two-dimensional perovskite precursor and a FAPbI₃ three-dimensional perovskite precursor that are mixed with a concentration ratio of 1:1.

In Example 4, the perovskite-precursor solution of the (NMA)₂PbI₄ two-dimensional perovskite precursor (of a band gap of 2.45 eV) and the FAPbI₃ three-dimensional perovskite precursor (of a band gap of 1.47 eV) that are mixed with a concentration ratio of 1:1 may be spread-coated onto the surface of the down-conversion luminescent layer, and after the solvent has volatilized, the sequential crystallization of the perovskite starts, thereby forming the perovskite layer of the three-dimensional-quasi-two-dimensional-two-dimensional structure in the direction from the shadow surface to the light facing surface. The prepared perovskite layer can absorb photons whose band gap is within the range of 2.45-1.47 eV, and emit 845 nm photons, to realize the function of down-conversion.

An embodiment of the present disclosure further provides a photovoltaic module, wherein the photovoltaic module includes the solar cell according to the first aspect.

An embodiment of the present disclosure provides another photovoltaic module, wherein the photovoltaic module includes the crystalline-silicon cell unit, a first encapsulation layer, the perovskite layer, the down-conversion luminescent layer and a cover-plate glass that are located on the light facing surface of the crystalline-silicon cell unit, and a second encapsulation layer and a back plate that are located on the shadow surface of the crystalline-silicon cell unit; and
the perovskite layer and the down-conversion luminescent layer are located between the light facing surface of the crystalline-silicon cell unit and the first encapsulation layer; or
the perovskite layer and the down-conversion luminescent layer are located between the first encapsulation layer and a shadow surface of the cover-plate glass.

In an embodiment of the present disclosure, in the practically produced photovoltaic module, the perovskite layer is merely required to be between the shadow surface of the cover-plate glass and the light facing surface of the crystalline-silicon cell unit. If the first encapsulation layer, the down-conversion luminescent layer and the perovskite layer exist between the light facing surface of the crystalline-silicon cell unit and the shadow surface of the cover-plate glass, the perovskite layer may be between the light facing surface of the crystalline-silicon cell unit and the first encapsulation layer, and may also be between the first encapsulation layer and the shadow surface of the cover-plate glass. In an embodiment of the present disclosure, if another functional layer exists between the light facing surface of the crystalline-silicon cell unit and the shadow surface of the cover-plate glass, the position of the perovskite layer is not particularly limited.

It should be noted that, regarding the process embodiments, for brevity of the description, all of them are expressed as the combination of a series of actions, but a person skilled in the art should know that the embodiments of the present application are not limited by the sequences of the actions that are described, because, according to the embodiments of the present application, some of the steps may have other sequences or be performed simultaneously. Secondly, a person skilled in the art should also know that all of the embodiments described in the description are preferable embodiments, and not all of the actions that they involve are required by the embodiments of the present application.

It should be noted that the terms “include”, “comprise” or any variants thereof, as used herein, are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “comprising a . . . ” does not exclude additional same element in the process, method, article or device comprising the element.

The embodiments of the present disclosure are described above with reference to the drawings. However, the present disclosure is not limited to the above particular embodiments. The above particular embodiments are merely illustrative, rather than limitative. A person skilled in the art, under the motivation of the present disclosure, can make many variations without departing from the spirit of the present disclosure and the protection scope of the claims, and all of the variations fall within the protection scope of the present disclosure.

1. A solar cell, wherein the solar cell comprises a crystalline-silicon cell unit, and a down-conversion luminescent layer and a perovskite layer that are sequentially located on a light facing surface of the crystalline-silicon cell unit;
a band gap of the perovskite layer gradually decreases in a direction from a light facing surface to a shadow surface; and
a band gap at the shadow surface of the perovskite layer is greater than or equal to a band gap of an absorbing layer of the crystalline-silicon cell unit.

2. The solar cell according to claim 1, wherein the down-conversion luminescent layer comprises a down-conversion luminescent material; and
the down-conversion luminescent material comprises a perovskite material or a luminescent quantum dot.

3. The solar cell according to claim 1, wherein the perovskite layer is ABX₃;
A is selected from at least one of methylamine ion, formamidine ion, phenylethylamine ion, 1-menaphthylamine ion and caesium ion;
B is selected from at least one of lead ion and tin ion;
X is selected from at least one of bromine ion, iodide ion and chloride ion; and
by regulating an element distribution in the perovskite layer of the ABX₃ in a thickness direction, the band gap of the perovskite layer gradually decreases from the light facing surface to the shadow surface.

4. The solar cell according to claim 1, wherein the band gap of the perovskite layer at the light facing surface is 2 eV-3.06 eV;
the band gap of the perovskite layer at the shadow surface is 1.2 eV-1.5 eV; and
a band gap of the down-conversion luminescent material in the down-conversion luminescent layer is 1.2 eV-1.5 eV.

5. The solar cell according to claim 1, wherein a thickness of the perovskite layer is 10 nm-100 nm.

6. The solar cell according to claim 1, wherein the solar cell further comprises an upper electrode, the upper electrode is formed at a hollowed-out position of the perovskite layer and the down-conversion luminescent layer, and the upper electrode does not directly contact the perovskite layer and the down-conversion luminescent layer.

7. A method for fabricating a solar cell, wherein the solar cell is the solar cell according to claim 1, and the method comprises:
providing the crystalline-silicon cell unit;
forming sequentially the down-conversion luminescent layer and a narrow-band-gap perovskite layer on the light facing surface of the crystalline-silicon cell unit, wherein a band gap of the narrow-band-gap perovskite layer is greater than or equal to the band gap of the absorbing layer of the crystalline-silicon cell unit; and
contacting a wide-band-gap perovskite material with the narrow-band-gap perovskite layer to perform ion exchange, to form a perovskite layer whose energy bands are in a gradient distribution, wherein a phase state of the wide-band-gap perovskite material is any one of a solid phase, a gas phase and a liquid phase, and a band gap of the wide-band-gap perovskite material is greater than the band gap of the narrow-band-gap perovskite layer;
or
providing the crystalline-silicon cell unit;
forming the down-conversion luminescent layer on the light facing surface of the crystalline-silicon cell unit; and
coating a perovskite-precursor solution onto the down-conversion luminescent layer, so that a perovskite precursor in the perovskite-precursor solution sequentially crystallizes to form the perovskite layer, wherein the perovskite precursor comprises a two-dimensional perovskite precursor and a three-dimensional perovskite precursor.

8. The method according to claim 7, wherein the phase state of the wide-band-gap perovskite material is a solid phase, and the step of contacting the wide-band-gap perovskite material with the narrow-band-gap perovskite layer to perform the ion exchange, to form the perovskite layer whose energy bands are in a gradient distribution comprises:
adding a powder of the wide-band-gap perovskite material onto a surface of the narrow-band-gap perovskite layer, and heating to perform the ion exchange between the wide-band-gap perovskite material and the narrow-band-gap perovskite layer, to form the perovskite layer whose energy bands are in a gradient distribution.

9. The method according to claim 7, wherein the phase state of the wide-band-gap perovskite material is a liquid phase, and the step of contacting the wide-band-gap perovskite material with the narrow-band-gap perovskite layer to perform the ion exchange, to form the perovskite layer whose energy bands are in a gradient distribution comprises:
soaking the crystalline-silicon cell unit having the narrow-band-gap perovskite layer in the wide-band-gap perovskite material to perform the ion exchange, to form the perovskite layer whose energy bands are in a gradient distribution, wherein the wide-band-gap perovskite material comprises any one of an ABX₃ perovskite solution, an AX precursor solution and a BX₂ precursor solution.

10. The method according to claim 7, wherein the phase state of the wide-band-gap perovskite material is a gas phase, and the step of contacting the wide-band-gap perovskite material with the narrow-band-gap perovskite layer to perform the ion exchange, to form the perovskite layer whose energy bands are in a gradient distribution comprises:
placing the crystalline-silicon cell unit having the narrow-band-gap perovskite layer in an atmosphere of the wide-band-gap perovskite material to perform the ion exchange, to form the perovskite layer whose energy bands are in a gradient distribution, wherein the wide-band-gap perovskite material comprises any one of an ABX₃ perovskite vapour, an AX precursor vapour and a BX₂ precursor vapour.

11. A photovoltaic module, wherein the photovoltaic module comprises the solar cell according to claim 1.

12. The photovoltaic module according to claim 11, wherein the photovoltaic module comprises the crystalline-silicon cell unit, a first encapsulation layer, the perovskite layer, the down-conversion luminescent layer and a cover-plate glass that are located on the light facing surface of the crystalline-silicon cell unit, and a second encapsulation layer and a back plate that are located on the shadow surface of the crystalline-silicon cell unit; and
the perovskite layer and the down-conversion luminescent layer are located between the light facing surface of the crystalline-silicon cell unit and the first encapsulation layer; or
the perovskite layer and the down-conversion luminescent layer are located between the first encapsulation layer and a shadow surface of the cover-plate glass.

13. The solar cell according to claim 2, wherein the solar cell further comprises an upper electrode, the upper electrode is formed at a hollowed-out position of the perovskite layer and the down-conversion luminescent layer, and the upper electrode does not directly contact the perovskite layer and the down-conversion luminescent layer.

14. The solar cell according to claim 3, wherein the solar cell further comprises an upper electrode, the upper electrode is formed at a hollowed-out position of the perovskite layer and the down-conversion luminescent layer, and the upper electrode does not directly contact the perovskite layer and the down-conversion luminescent layer.
